(19) United States
(12) Patent Application Publication
(10) Pub. No.: US 2011/0044002 A1
(43) Pub. Date: Feb. 24, 2011

(54) METHOD FOR ARRANGING COOLING FOR A COMPONENT AND A COOLING ELEMENT

(75) Inventors: Kimmo Jokelainen, Ii (FI); Aila Petajajarvi, Maksniesi (FI)

Correspondence Address: YOUNG & THOMPSON, 209 Madison Street, Suite 500, Alexandria, VA, 22314, US

(73) Assignee: Valtion Teknillinen Tutkimuskeskus, VTT (FI)

(21) Appl. No.: 12/864,137

(22) PCT Filed: Jan. 19, 2009
(86) PCT No.: PCT/FI09/50042

§ 371 Date: Oct. 4, 2010

(51) Int. Cl. H05K 7/20; H05K 13/00; F28F 13/00

(52) U.S. Cl. 361/704; 29/854; 165/135

(57) ABSTRACT

In the method according to the invention, the discrete electric component to be cooled is connected to the cooling element without a circuit board or substrate. In the method, a layer of insulating material is thermally sprayed on one surface of the cooling element. The connection points and conductors required by the discrete electric component are formed on top of this insulating layer. The discrete electric component is glued onto the insulating layer. Subsequently, the electrical connections for the discrete component are made. After the discrete component has been electrically connected, it can still be protected using a layer of thermally sprayed insulating material.

The present invention relates to a method for producing a cooling element for an electrical component. The invention also relates to a cooling element produced according to the same method.

### PRIOR ART

The temperature control of electrical components, which use a lot of electricity as compared to their size and are a part of electrical appliances, has a decisive effect on their operation. Examples of such components are power semiconductors, processor units and light components such as a light diode, commonly known as a LED (light emitting diode).

The operating temperature of an electrical component may be reduced using appropriate cooling. As a result of the reduced temperature the electrical component can run more effectively as regards its use and/or the lifespan of the component is extended. The temperature of an electrical component can be reduced using for example a separate fan, which is used to direct cooling air passed the component to be cooled. The component to be cooled can also be connected to a separate cooling element.

FIG. 1 shows a known method for connecting a heat generating electrical component into cooling element 14. The electrical component to be cooled 11 has been connected to a circuit board or to a substrate 12. The circuit board or substrate 12 comprises connecting points for the electrical component. A conductive pattern can also be formed into it for connecting electrical component 11 to an electric circuit arrangement. In the case of FIG. 1 circuit board 12 has been glued onto cooling element 14 in use with an appropriate type of glue, which conducts heat easily, known as thermoset glue 13. The circuit board/substrate 12 and glue 13 represent a thermal resistance, the amount of which has an effect of the cooling capacity of the illustrated structure. The thicker the above-mentioned elements 12 and 13 are and the less heat they conduct, the higher the temperature of the electrical component 11 to be cooled will rise. In an electrical component, a rise in heat of even a few degrees may reduce its lifespan considerably or limit the maximum feed power.

In view of the operation and lifespan of an electrical component, it would be preferable to have an element between the electrical component and the heat sink, the heat resistance of which is as little as possible.

### SUMMARY OF THE INVENTION

The object of the invention is to present a method and cooling structure whereby the cooling of an electronic component may be made more effective as compared to prior art solutions.

The objects of the invention may be reached using a cooling structure in which the electronic component to be cooled is installed onto the cooling element to be used without a separate support element (a circuit board or substrate). In a cooling arrangement according to the invention a thin layer of insulating material is formed onto the surface of the cooling element using so-called thermal spraying. Thermal spraying is a method by which an insulating or conductive material is blown onto a gas flame. The material to be blown may be in the form of for example a liquid, powder, paste, wire or gas. The material to be blown heats up and is sintered onto the surface of the cooling element or other mechanical structure. Typically, the insulating material used may be of ceramic such as aluminium oxide Al₂O₃. Thermal spraying does not actually heat the target or its heating effect in the target is relatively small. If needed, connecting points and circuit patterns may be set on top of the insulating layer, necessary to connect the electronic component to an electronic circuit arrangement. The electronic component may be fixed onto the insulating layer using a prior art method, either with or without a casing. The fixing may be done, for example, by gluing, soldering or bonding. Advantageously the electronic component may be protected with a layer of suitable material after it has been fixed onto the cooling element.

An advantage of the invention is that the thermal resistance between the electrical circuit element and cooling element is small as compared to known solutions.

A further advantage of the invention is that a separate support element (circuit board or substrate) is not needed.

A further advantage of the invention is that due to the increased cooling capacity the electric power of the electronic component can be raised as compared to known solutions.

A further advantage of the invention is that the lifespan of the electronic component is extended because the operating temperature of the component may be lowered.

A further advantage of the invention is that the electronic component may be fixed onto the cooling element either with or without a casing.

A further advantage of the invention is that the electronic component can be hermetically protected, either during installation or later.

A further advantage of the invention is that there are fewer stages of production as compared to traditional production methods, which means lower production costs.

Yet another advantage of the invention is that by using it electric components can be integrated onto a three-dimensional surface.

Still another advantage of the invention is that an electric component may be integrated onto the existing structure where it is used.

The method according to the invention is characterized in that
a thermally insulating layer of material is blown onto at least one surface of the element or onto a part of the surface,
connecting points and conductors necessary for the electrical connection of a discrete electric component are formed on top of the insulating layer,
at least one discrete electric component is connected on top of the layer of insulating material, and
the discrete electric component is connected to the connecting points formed on top of the layer of insulating material.

The cooling element for cooling a discrete electric component according to the invention is characterized in that
a sintered layer's insulating material is on the surface or part of the surface of the cooling element onto which at least one discrete electric component is to be connected,
connecting points and conductors and necessary for electrically connecting the discrete electric component have been formed on top of the insulating material, and
a means for fixing the discrete electric component onto the insulated surface of the cooling element have been created.

Some of the advantageous embodiments of the invention have been presented in the dependent claims.

The basic idea of the invention is as follows: advantageously, thermal spraying is used in the production of the cooling arrangement according to the invention. Thermal spraying is a method by which material that is entirely or partly melted into a liquid is blown or sprayed as a fine spray together with for instance a flow of gas onto the surface to be treated. Various methods used for thermal spraying include for instance flame spraying, electric arc spraying, laser spraying, arc spraying, plasma spraying, vacuum plasma spraying, high-velocity flame spraying and detonation spraying.

In the first phase of the production method according to the invention, a thin layer of ceramic material is thermally sprayed onto the surface or part of the surface onto which the electric component will be fixed. The surface can be either planar or it can contain shapes essentially differing from the plane (3D object). Advantageously, in the second phase, the connecting pins or contact surfaces needed for the circuit board may be formed on top of the ceramic layer, together with the conductors needed for connecting the electric circuit with the rest of the circuit entity. Subsequently the electric component is fastened onto the ceramic layer using, for example, glue that conducts heat easily or using another prior art fastening method. If necessary, the connectors of the electric component are connected to the connecting pins formed on top of the ceramic layer. If necessary, the electric component may be hermetically or electrically protected by thermally spraying a suitable material on top of it.

In the following the invention is described in detail. In the description, a reference is made to the enclosed drawings, in which

FIG. 1 shows a prior art cooling structure solution,

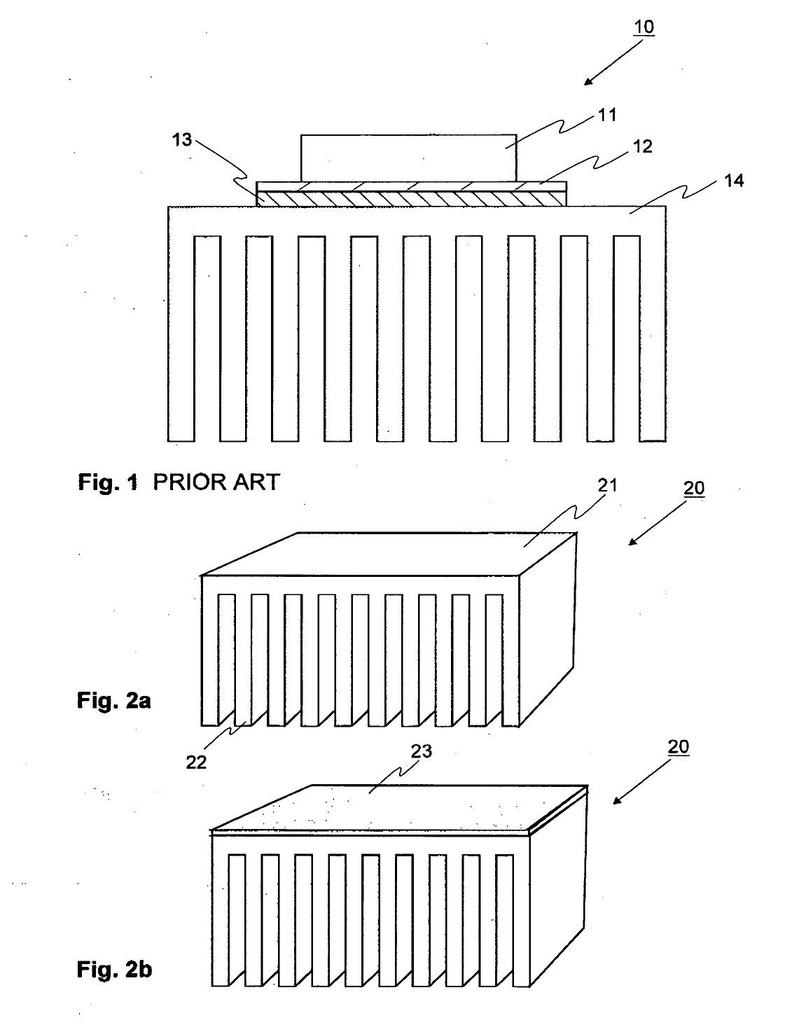

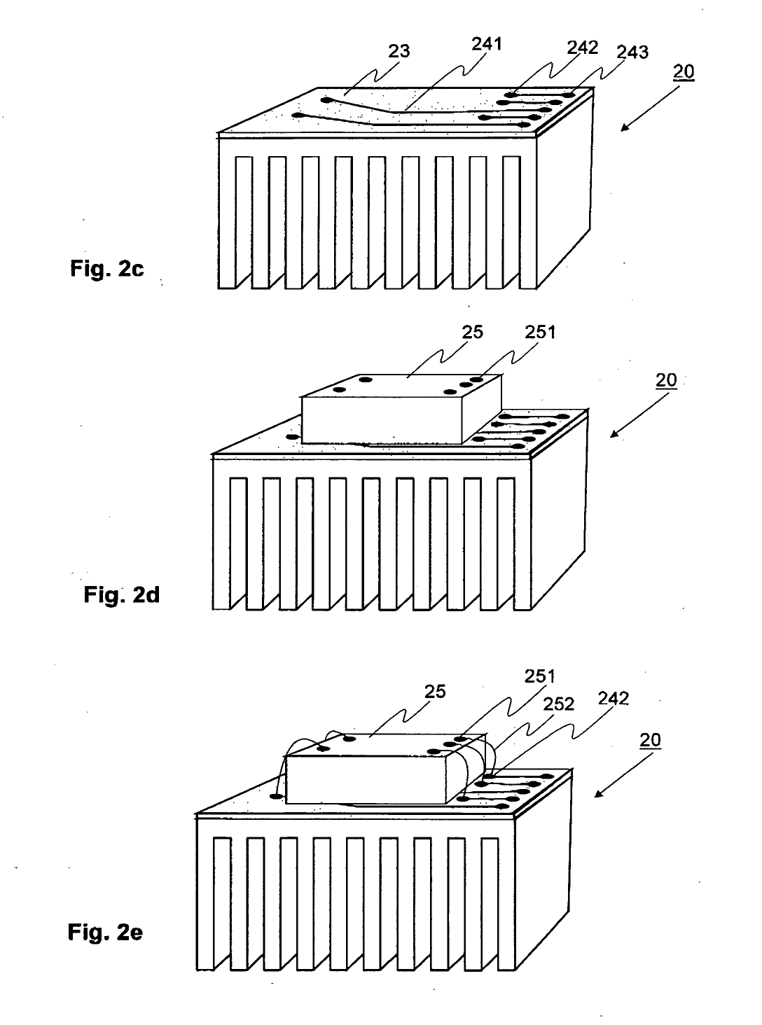

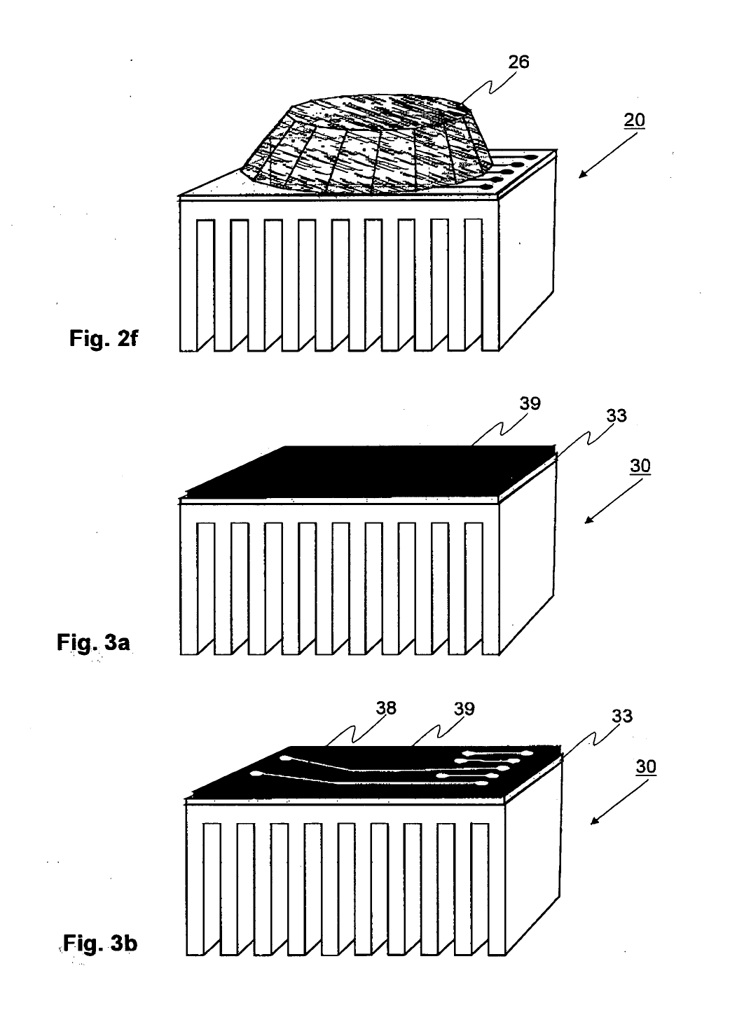

FIGS. 2a-2f show a method of construction of a cooling element structure according to the first embodiment of the invention,

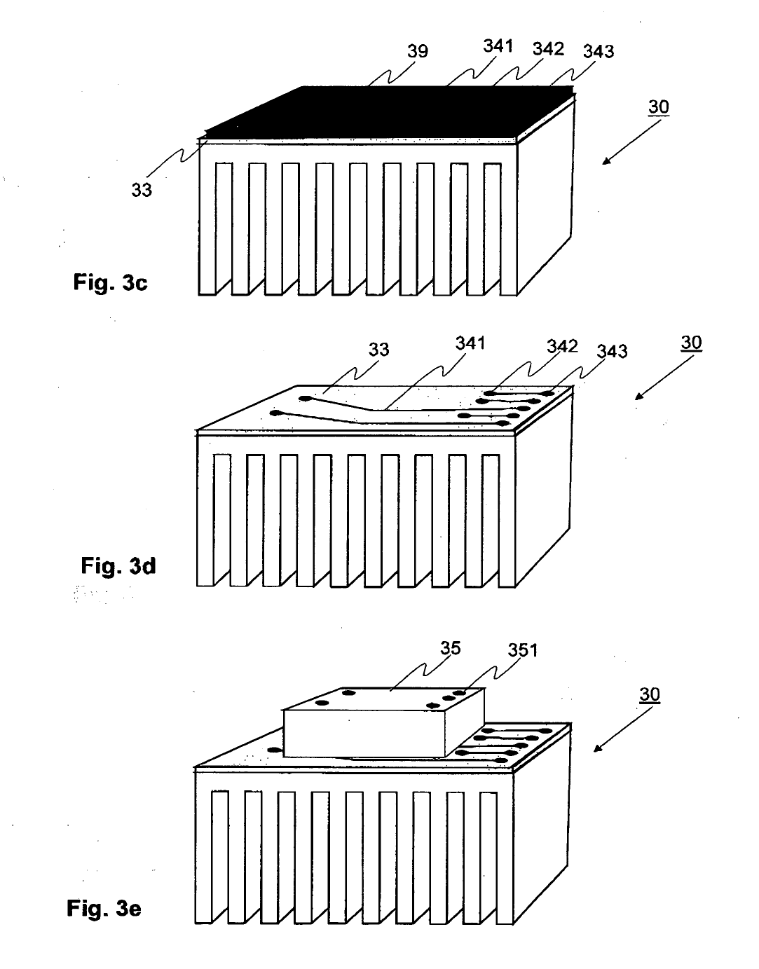

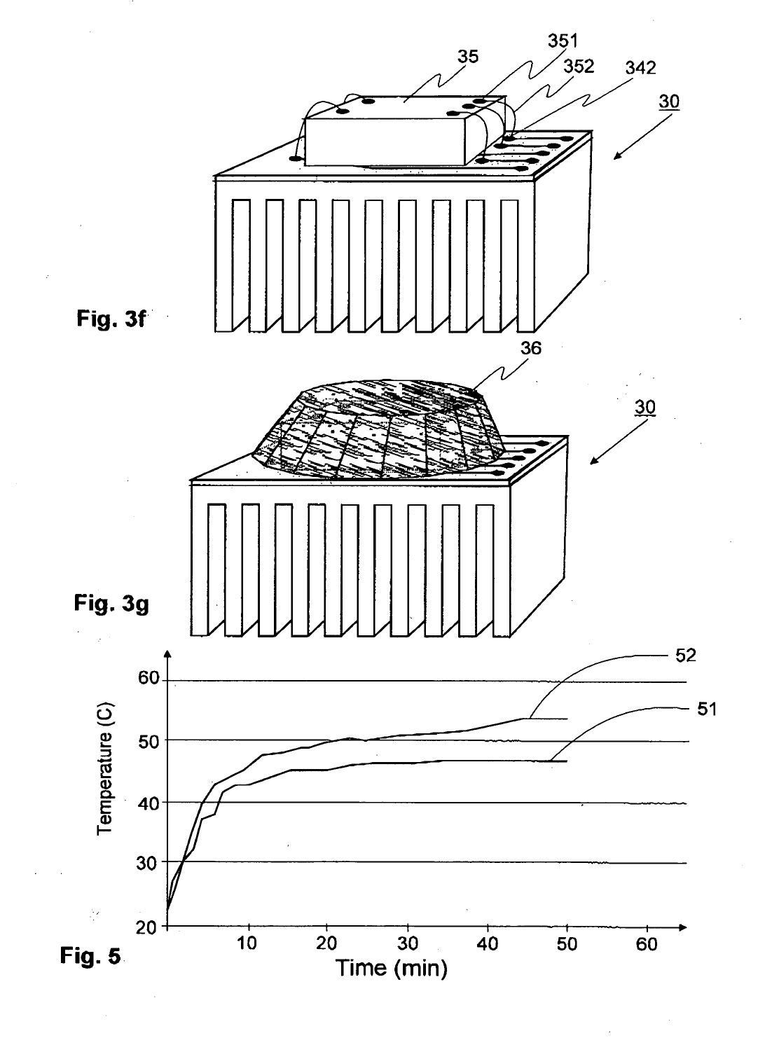

FIGS. 3a-3g show a method of construction of a cooling element structure according to the second embodiment of the invention,

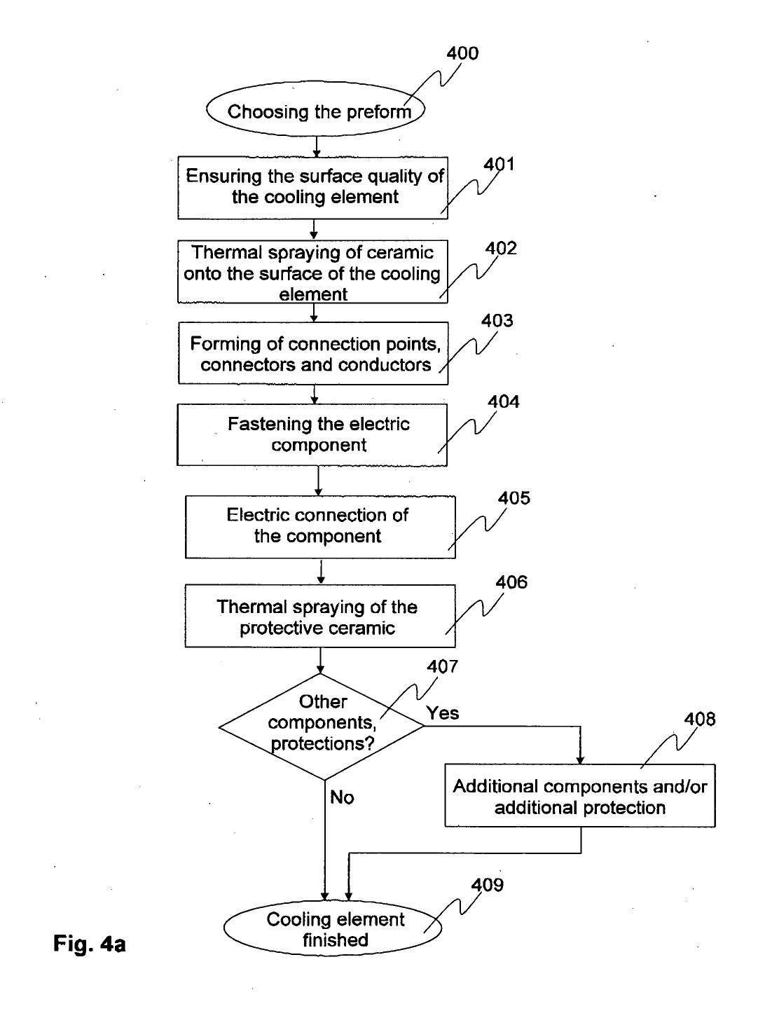

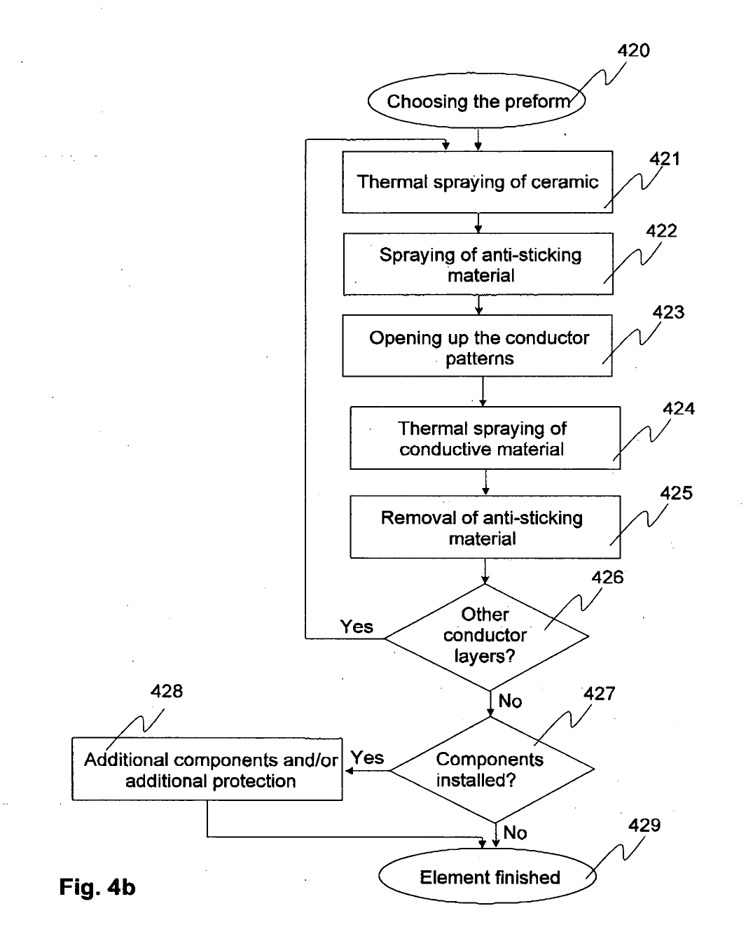

FIG. 4a shows, by way of example, a flow chart of the main stages of the method of construction of the cooling structure of an electric component according to the first embodiment of the invention,

FIG. 4b shows, by way of example, a flow chart of the main stages of the method of construction of the cooling structure of an electric component according to the second embodiment of the invention, and

FIG. 5 shows a comparison of the warming up of a cooling element according to the invention and a prior art cooling element.

In the following description the embodiments are only examples and a person skilled in the art may also put into practice the basic idea of the invention in another way than that described. Although the explanation might refer to an embodiment or embodiments in several places, it does not mean that the reference is meant for only one of the described embodiments or that the characteristic described would only be useful in one of the described embodiments. The separate characteristics of two or several embodiments may be combined and thus create new embodiments of the invention.

FIG. 1 is presented in connection with the description of the prior art.

A circuit board or substrate to support the electric component is not necessarily needed between the cooling element according to the invention and the electric component fastened onto it. In the first stage of the method of construction according to the invention, a thin layer of insulating material is formed onto the surface of the cooling element using so-called thermal spraying. Thermal spraying is a method by which suitable plastic, metal or ceramic powder or wire is blown by compressed air onto, for example, a gas flame. Instead of a gas flame thermal spraying can also utilize for instance an electric arc or laser for heating the material to be blown. The powder or wire heats up and is sintered onto the surface of the object which is the target of the blowing. Thermal spraying does not actually heat the object or the heating effect directed at the object sprayed is only minor.

The electric component to be connected to the cooling element according to the invention may be glued on top of the layer sprayed and sintered on top of the cooling element without using any structures in between, either with or without a casing. Advantageously, the electric component may be protected with a layer of suitable material after it has been fixed onto the cooling element.

Typically the insulating material used in thermal spraying may advantageously be functional plastics or ceramics, such as aluminium oxide Al₂O₃. Other advantageous materials to be used as an insulating ceramic include for instance MgTiO₃, CaTiO₃, ZnO, SiO₂, B₂O₃, Al₂O₃ alloys, BaTiO₃, Ba₁₋ₓSrₓTiO₃, PbO, BeO, SiC, AlN, Si, Si₃N₄, diamonds, quartz, steatite, titanate, mullite, alumina or glass and alloys of the aforementioned.

If needed, connecting points and circuit patterns may be set on top of the insulating ceramic layer, necessary to connect the electric component to an electronic circuit arrangement. The forming of the connecting pins and conductors may advantageously be created using for example thermal spraying, paste printing, photolithography, growing, using an etching process, transfer printing technique, decal technique, photo-gravure, or an inkjet method.

Materials suitable for thermal spraying, which also conduct electricity to produce conductors, are for example gold, silver, copper, aluminium, palladium, molybdenum, wolfram, TiO₂, BaCO₃, CoO, NiO, CuO, Mn₃O₄, RuOₓ, tantalum-aluminium alloys, kovar, kanthal, nichrome, manganese and other corresponding materials, such as conductive plastics and alloys of the aforementioned substances.

Thermal spraying can be used to form layers on top of the ceramic layer using other materials that have the desired electrical or electro-mechanical effects. Such materials are for example various piezoelectric materials, such as zirconium oxide, titanium oxide, and PZT. Also ferroelectric or ferromagnetic materials may be utilized, such as Fe₃O₄, AlB₂, ZnO.

Thermal spraying may also be used to make layers of other materials on top of the ceramic surface. Some examples of possible materials include various rubbers, polyimides, polyamides, polyesters, and various forms of epoxy, various forms of resin, bismaleimide-triazine alloys, kaptones, aramides and functional plastics.

FIGS. 2a-2e show the method for producing a cooling element according to the first embodiment of the invention and the cooling element itself. The method for production shown in FIGS. 2a-2e can be advantageously used in the event the electric component requiring cooling can be fixed onto such a surface of the cooling element blank which is essentially plane-shaped.

The manufacturing of the cooling element of the electric component may be initiated using either a conductive or a dielectric material. If the base material, the cooling element preform, is dielectric as such, manufacturing can be initiated by directly producing conductor structures on top of the dielectric base material. The easiest way to produce simple wire structures (such as RFID antennae) is to blow a metallic substance onto the dielectric base material through a mask forming the conductor pattern in which case a pattern according to the aperture in the mask is repeated directly onto the base surface.

The preparation of an electrically operating 3D cooling element is initiated advantageously by blowing for instance ceramic material onto either a metal or ceramic bottom plate or onto the body of the device or onto another mechanical structure. Subsequently, the circuit patterns necessary to attach the electric component on top of the ceramic material in the cooling element are formed by way of, for instance, thick film printing, photolithography, laser sintering, thermal spraying or by another prior art method. If for example thick film printing or other prior art production method is used, the conductor may be “sintered” using a gas flame whereby the thermal spraying is also performed or traditionally by heating in an oven. A new conductor pattern may be blown on top of the insulating layer using for example a separate mask to ensure that the conductor pattern made during the previous phase stays uncovered at the “vias”. Subsequently a new layer of conductors is prepared in the same way as the previous one. By repeating these process stages a 3D wire pattern can be made inside aluminium oxide, for example.

Advantageously, silicon chips can also be integrated into the cooling element structure according to the invention. To electrically bond a silicon chip, conductor patterns may advantageously be printed or formed otherwise on top of the insulating material (e.g. ceramic prepared by thermal spraying). Advantageously, a silicon chip is bonded onto the conductor patterns with wire connections using for instance the flip chip method. Subsequently the silicon chip is advantageously protected with a prior art so-called glob-top material or other prior art protective material with an epoxy base for instance. After the silicon chip has been electrically connected and protected with the glob-top material, the entire structure can advantageously be embedded into the ceramic using thermal spraying. This results in a hermetically sealed ceramic structure which is extremely reliable and durable. If for instance aluminium oxide is used as the base material, its heat expansion coefficient is in the same range as that of silicon. This results in the structure being durable.

It is also possible that components may be attached on top of the ceramic using traditional flip chips or the SMD technique in addition to the wire connection components described above, and it is possible to protect these components using material layered on top of them using thermal spraying.

In addition to the silicon chip connections described above, passive components may also be immersed onto the surface of the cooling element according to the invention, these including resistors, capacitors and coils.

Thermal spraying may advantageously be applied to protect prepared structures using the low temperature co-fired ceramic technique (LTCC technique), for example in the way described below. An LTCC module the surface of which has a silicon chip and is glob-top protected may be embedded into the ceramic structure using thermal spraying. A glob-top protected silicon chip does not suffer damage if low-temperature ceramic, LTCC powder, plastic or alumina is layered on top of it using thermal spraying. The functionality of such a structure is also strengthened by the heat expansion coefficients of alumina and LTCC ceramics which are very close to each other.

A thin ceramic layer is ideal when good heat conduction from an electric structure to an underlying metallic body is needed. For instance an application with a heat-retaining silicon chip may be built on top of a ceramic layer laid on top of metal. The metal frame acts as a cooling plate into which the heat produced by the silicon is conducted. The metal frame may also comprise for example a spiked structure. The thickness of the ceramic layer is advantageously ca. 50 μm. The connecting pins needed to electrically connect the silicon chip can advantageously be created for instance using thick film printing.

FIGS. 2a-2e show, by way of an example, a construction of a power electronics application of the cooling element according to the first embodiment of the invention.

The construction of the cooling element begins by thermally spraying a thin coat of insulating material which conducts heat as much as possible for instance on one surface of the cooling element. The surface or part of a surface which is coated with the thermally sprayed material may be either plane-shaped, or advantageously it can also have shapes essentially differing from the plane shape (a 3D object).

Subsequently, conductor patterns used for connecting components are formed on top of the ceramic surface. The conductors can be formed using for instance thermal spraying, paste printing, photolithography, growing, etching, using an inkjet, or using any other prior art method for constructing conductors.

Subsequently the silicon chip, the cooling of which is critical, is glued onto the cooling element.

Subsequently, the silicon chip is connected to the rest of the circuit entity by advantageously making use of so-called wire bonding.

Subsequently, sensitive components are protected using for instance glob-top material.

In an advantageous embodiment of the invention the structure is protected using thermal spraying for coating it advantageously with a ceramic protection material.

FIG. 2a shows preform 20 of the cooling element according to the first embodiment of the invention from which the cooling element is manufactured. Cooling element 20 comprises an essentially plane-shaped surface 21 onto which the heat producing electric component is fastened. To improve the evaporation of heat the blank of the cooling element can advantageously also comprise ribs 22. The shape of the ribs can be chosen according to the cooling efficiency needed by the object used.

The cooling structure can also be large, either in mass or area, as compared to the electric component to be cooled. In an advantageous embodiment of the invention the cooling structure can also be a structural component belonging to an appliance or to the frame of the structure which easily conducts heat. In these advantageous embodiments the electric component does not necessarily need a separate cooling element.

In FIG. 2b an electrically insulating layer of material 23 has been thermally sprayed onto the essentially plane-shaped surface of the cooling element preform. The thickness of the insulating material layer 23 may vary from a few parts of a micrometer to a few hundred micrometers. Advantageously the layer 23 blown onto the plane-shaped surface is of a ceramic, sintering material or plastic.

FIG. 2c shows conductors 241 formed on top of the thermally sprayed, insulating layer 23, the outer connection points 242 for an electric component, as well as connectors 243, by which the electric component 25 to be cooled is configured to be connected as a part of a circuit (not shown in FIG. 2c). The conductors 241, the outer connection points 242, and connectors 243, are shaped on top of the insulating layer 23 using a prior art technique. Some appropriate patterning methods are for example thick film printing, photolithography, laser sintering or thermal spraying.

FIG. 2d shows an electric component 25 attached on top of the insulating layer 23. The attachment may be done for example by gluing the component 25 onto the layer 23. Advantageously, the glue used is so-called thermoset glue, which has good heat-conduction properties. The upper surface of the electric component 25 to be attached includes an example of connection points 251 used for the electric component 25.

In FIG. 2e the connection points 251 of electric component 25 have been connected with wires 252 onto the outer connection points 242 of the component situated on top of the insulating layer 23. In an advantageous embodiment of the invention the electric component is ready for use after the wire connections have been made.

In an advantageous embodiment of the invention the electric component 25 is a so-called flip chip component. A flip chip component has on one side soldering balls corresponding to the connection points. When a flip chip component is attached to a base structure, such as a circuit board, the side of the flip chip component with the soldering balls is placed against the circuit card or similar structure. In the arrangement according to the invention, the soldering balls of the flip chip component are placed against the outer connection points 242 on the ceramic surface 23. The soldering balls of the flip chip component can be melted together with the component connection points 242 using for instance ultra sound or heat.

In FIG. 2f the electric component 25 is also protected with an example layer of material 26. The layer of material 26 has been thermally sprayed on top of component 25 to be protected. Advantageously, component 25 is protected at least with an insulating coat of ceramic material. In an advantageous embodiment of the invention a layer of conductive material is blown on top of the insulating ceramic layer, which results in an electric protection around component 25. The protection may be for instance an electro-static discharge (ESD) or an electro-magnetic pulse (EMP) shield.

FIGS. 3a-3g show, by way of an example, a construction of a power electronics application of the cooling element according to another advantageous embodiment of the invention. Although the examples in FIGS. 3a-3g show the fastening and protection of the electric component onto the plane-shaped surface of the cooling element, this embodiment is also advantageously suited for the forming of wiring required by electric components, and also for fixing components onto surfaces that are not plane-shaped.

In FIG. 3a, initially an electrically insulating layer of material 33 has been thermally sprayed on the surface of cooling element preform 30. This layer can advantageously be of a ceramic material. The thickness of the insulating layer of material 33 can vary from some tens of micrometers to a few hundred micrometers. FIG. 3a shows how also layer 39 of an appropriate material preventing sticking has been sprayed on top of the previous layer.

FIG. 3b shows how the anti-sticking material 39 has been opened advantageously by laser to create space for the connection points and conductors 38 needed for the connection of the electric component.

FIG. 3c shows the situation after conductive material has been thermally sprayed onto the anti-sticking layer 39 at the opened conductors 341, connection points 342 and connectors 343.

FIG. 3d shows the situation after anti-sticking material 39 has been removed from the surface of ceramic layer 33. The removing of the anti-sticking material can be done either chemically or mechanically. After the anti-sticking material has been removed, conductors 341, connection points 342, and connectors 343 are suitable for fastening the electric component 35 onto the cooling element preform 30.

In FIG. 3e the electric component 35 has been fastened onto the cooling element preform 30. The fastening may advantageously be done by gluing.

FIG. 3f shows the situation after connection points 351 of the electric component have been connected with wires 352 onto the connection points 342 in the cooling element preform 30.

In FIG. 3g the electric component 35 has been protected with the thermally sprayed layer 36. The layer 36 may either be merely isolating ceramic or an alloy, in which the ceramic layer is on top of electric component 35, and another material, such as plastic, has been thermally sprayed on top of this layer.

In another advantageous embodiment of the invention, the manufacturing process shown in FIGS. 3a-3d is repeated several times before the electric component or components 35 are fastened onto the cooling preform 30. In this embodiment the finished conductors 341 shown in FIG. 3d, the connecting points 342 and connectors 343 are advantageously covered at least partly with a new thermally sprayed layer of ceramic material. After the thermal spraying the situation is in principle the same as is shown in FIG. 2a, in which the insulating ceramic layer 23 is on top. In this embodiment anti-sticking material is advantageously sprayed on top of the ceramic layer for a second time. Using the method described above, new conductors, connecting points, connectors or vias can be patterned into the anti-sticking material. Subsequently, thermally conductive material is blown into the patterns opened into the anti-sticking material. Subsequently the anti-sticking material is again removed.

If the plan is to prepare yet another new layer of conductors or several layers of conductors before the components are connected onto the preform, yet another layer of insulating ceramic is thermally sprayed onto applicable points on the surface of the cooling element preform. Subsequently, the next layer of conductors is prepared using the method described above.

In another advantageous embodiment of the invention, the circuit entity can also advantageously be equipped with passive components, including resistors, coils or capacitors, using thermal spraying in places where the anti-sticking material has been removed. If necessary, the prepared passive components can still be protected with a layer of thermally sprayed ceramic.

Using the method described above, a multi-layered circuit entity can be prepared, into which discrete components can still be attached using prior art methods after all the wiring layers have been prepared. For instance, discrete electric components that require cooling, such as silicon chips, can be attached to the cooling element 30 according to the invention, after the wiring and passive components made using thermal spraying have been finished.

In an advantageous embodiment of the invention, components shown in FIGS. 2f and 3g can be injection moulded inside plastic, for instance. The components according to the invention can be equipped with various optical elements or characteristics using injection moulding. These elements can be used, for instance, to shape the cone of light or the distribution of light emitted by a LED as desired.

FIG. 4a shows, by way of example, a flow chart of the manufacturing of a cooling element shown in FIGS. 2a-2f. In stage 400 the cooling element preform onto which electric components are attached is chosen.

In stage 401 the quality of the surface of the cooling element is examined for the section onto which electric components are to be connected. At this stage, the surface of the cooling element can, if needed, be treated in such a way that the thermally sprayed ceramic material sticks onto the surface of the cooling element acting as the base for the electric components.

During stage 402 a layer of thermally isolating material is thermally sprayed onto the chosen surface of the cooling element. Advantageously this material is ceramic or plastic. The thickness of the layer of ceramic or plastic is determined according to use. An isolating layer in the micrometer range is sufficient for low-voltage components. On the other hand, in the case of a high voltage electric component, isolating it from the cooling element may call for an insulation layer in the millimetre range.

During stage 403, conductors, connecting points and connectors are patterned on top of the ceramic layer. The said pattern can be prepared using a prior art method. Some appropriate methods are for example thick film printing, photolithography, laser sintering or thermal spraying.

During stage 404, the electric component or components to be cooled are fastened, advantageously by gluing. In addition to the electric component to be cooled, other discrete components can also be installed on top of the cooling element according to the invention.

During phase 405 the electric component requiring cooling is electrically connected to the rest of the circuit entity on the cooling element. The electrical connection can be done for instance by using separate wires. Other prior art ways of connecting discrete components are also possible. An alternative way of connecting the component is to use a flip chip connection.

During stage 406 a protective layer is thermally sprayed on top of the circuit entity. The protective layer may cover the circuit entity on top of the cooling element, either completely or partially. An aperture may be left in the sprayed protective layer, for instance for the light-emitting part of a LED or for a light-sensitive cell acting as a light receptor. The protective layer may also comprise several sprayed layers in which different materials have been used. However, advantageously the layer next to the cooled component is of a ceramic material. Advantageously a thin layer of conductive material for instance can be sprayed on top of it to create an electric protection.

During stage 407 an inspection is made to determine whether or not all the components intended for the cooling element have been connected. If there are still other discrete components left unconnected, they are connected during phase 408 if necessary. These components are not protected after the connection. After the connection is finished, the process ends in stage 409.

In the event the cooling element is considered to be finished in stage 407, the process ends in stage 409 at which time the cooling element according to the invention is ready for installation into its location of use.

FIG. 4b shows, by way of example, a flow chart of the manufacturing of a cooling element according to another advantageous embodiment of the invention. To a man skilled in the art, it is obvious that the said method can also be used to manufacture other electric circuits in addition to the cooling element and the electric components connected that was used as an example. Thus the invention is not restricted to the manufacturing of a cooling element; rather, the method also makes it possible to build other electric circuit solutions onto the surface of a chosen element.

FIG. 4b shows stage 420 during which a preform is chosen to be used as the cooling element of the electric component as the example on FIG. 4b indicates.

During stage 421 an insulating layer of ceramic material is thermally sprayed onto at least one surface of the chosen cooling element. The thickness of the sprayed layer can be adjusted according to the requirements of the electric component being installed.

During stage 422 a layer of anti-sticking material is sprayed on top of the ceramic insulation layer.

During stage 423 the locations for the circuit patterns, connection points and connectors are opened into the anti-sticking material advantageously using laser.

During stage 424 thermally conductive material is sprayed into the opened circuit patterns, connection points and connectors. The thermally sprayed conductive material does not stick onto the spots in the cooling element which have anti-sticking material.

During stage 425 the anti-sticking material is removed either chemically or mechanically. At this stage the conductors, connection points and connectors formed on top of the ceramic layer are exposed.

During stage 426 it is determined whether other layers of conductors are to be made or whether the possible discrete components are to be connected to the formed connection points. In the event it is decided during stage 426 that at least one other layer of conductors is to be made, the process returns to stage 421.

During stage 421 a new layer of ceramic is thermally sprayed. During this round of the process, the ceramic is sprayed on top of the conductors and connectors formed during the first round of the process. Thermal spraying can be used to cover the conductors and connection points prepared during the previous round of the process either completely or partly. By repeating stages 421-426, several overlapping layers of conductors, which are isolated from each other, can be made.

At the end of a round of the process, at stage 426, it is decided that all the necessary layers of conductors on the cooling element have been finished. After this, the process is taken to stage 427 during which an inspection is made to determine whether or not discrete components are to be installed onto the finished cooling element preform. The discrete components can be either active or passive.

In the event no discrete components are installed, the element preform is ready for installation or connection to its actual location of use in stage 429.

If during stage 427 it is determined that additional discrete components are still to be connected to the cooling element preform, the process progresses to stage 428. The connecting points and connectors, to which the discrete electric components are connected, have been prepared into the cooling element preform using the process described above. The connection of discrete components to the element preform is done in the way described in stages 404-409 of the flow chart in FIG. 4a. Going through these stages, chosen parts of the discrete components can be connected and protected inside the ceramic material.

Using the methods described above, light sources can be produced, for instance, in which a LED or several LEDs have been fastened, using the method according to the invention, onto the cooling element acting as a base for the LEDs. FIG. 5 shows a test that depicts the heating up of a LED connected to the cooling element according to the invention. The horizontal axel shows the time the LED is switched on. The vertical axel shows the temperature of the LED at a given moment. The temperature behaviour of the cooling element according to the invention has been shown in reference 51. For comparison, reference 52 shows the temperature behaviour of a prior art cooling element as a function of time.

The final temperature of a cooling element structure according to the invention is ca. 10 degrees centigrade lower than the final temperature of the prior art cooling element solution used for comparison. The lower temperature of the cooling element according to the invention increases the lifespan of the LED, if the light power is not increased. Alternatively, if lengthening the lifespan is not the goal, the light power of the LED can be raised as compared to the cooling element according to prior art.

Some advantageous embodiments of the method and appliance according to the invention have been described above. The invention is not restricted to the solutions described above, but instead the idea according to the invention can be applied in numerous ways within the limits set by the claims.

1. A method for producing an element containing electric circuits, characterized in that
an insulating layer of material (23, 33) is thermally sprayed (402, 421) onto at least one surface of an element (20, 30) or onto a part of the surface,
connection points (242, 252) and conductors (241, 251) needed for an electric connection of a discrete electric component are formed (403, 422, 423, 424) on top of the insulation layer,
at least one discrete electric component (25, 35) is connected (404, 428) on top of the layer of insulating material, and
a discrete electric component is connected (405) to the connecting points formed on top of the layer of insulating material.

2. The method according to claim 1, characterized in that a layer of insulating material (26, 36) is thermally sprayed (406, 428) on top of the installed and connected discrete electric component (25, 35).

3. The method according to claim 2, characterized in that a layer of conductive material is thermally sprayed on top of the insulating material.

4. The method according to claim 3, characterized in that the insulating material is either a ceramic substance or plastic.

5. The method according to claim 1, characterized in that the connection points and conductors are formed using one of the following methods: thick film printing, photolithography, transfer printing technique, decal technique, photo-gravure, inkjet, laser sintering or thermal spraying.

6. The method according to claim 1, characterized in that the forming of the connection points and conductors comprises
spraying an anti-sticking material (39) on top (422) of the insulating material (33),
opening of the shapes for the connection points and conductors by laser (423),
filling up of the opened connection points and conductors with a conductive material using thermal spraying (424), and
removal of the anti-sticking material (425).

7. The method according to claim 1, characterized in that the element (20, 30) is a cooling element for the discrete electric component (25, 35).

8. A cooling element (20, 30) for cooling a discrete electric component (25, 35), characterized in that it comprises
a layer of sintered (23, 33) insulating material on a surface or part of the surface of the cooling element to which at least one discrete electric component is arranged to be connected,
connecting points (242, 342) and conductors (241, 341) needed for the electrical connection of the discrete electric component have been formed on top of the insulating material, and
means for fastening the discrete electric component to the insulated surface of the cooling element.

9. The cooling element according to claim 8, characterized in that the sintered insulating layer (23, 33) is either a ceramic substance or plastic.

10. The cooling element according to claim 9, characterized in that the thickness of the sintered insulating layer is in the range of 0.1-1000 μm.

11. The cooling element according to claim 10, characterized in that the connection points (242, 342) and conductors (241, 341) formed on top of the sintered insulating layer have either been thick film printed, or finished using photolithography, transfer printing technique, decal technique, photo-gravure, inkjet, laser sintering, or thermal spraying.

12. The cooling element according to claim 11, characterized in that the discrete electric component (25, 35) has been arranged for fastening to the sintered insulating layer (23, 33) with glue.

13. The cooling element according to claim 12, characterized in that the discrete electric component (25, 35) has been arranged for electric connection using either wire connections (252, 352) or flip chips on the connection points (242, 342).

14. The cooling element according to claim 13, characterized in that the discrete electric component being connected (25, 35) is a LED.

15. The cooling element according to claim 14, characterized in that the LED, connection points and conductors have been arranged for protection with at least one layer of thermally sprayed material (26, 36).

16. The cooling element according to claim 8, characterized in that the connection points and conductors have been arranged for production
by spraying an anti-sticking material (39) on top (422) of the layer of insulating material (33),
by opening the connection points and conductors using laser on the layer of anti-sticking material (423),
by filling up the opened connection points and conductors (424) using thermal spraying, and
by removing the anti-sticking material (425).

17. The cooling element according to claim 10, characterized in that the surface or part of the surface of the cooling element, onto which the electric component has been arranged to be connected, is at least partly three-dimensional.

18. The cooling element according to claim 10, characterized in that the device, to which the electric component has been connected, is a structural component with either a great mass or great area, arranged to act as the cooling element for the electric component.
